(19) United States
(12) Patent Application Publication
(10) Pub. No.: US 2020/0204160 A1
(43) Pub. Date: Jun. 25, 2020

(54) DUAL-BAND IN-PHASE AND QUADRATURE-PHASE (I/Q) SIGNAL GENERATING APPARATUS AND POLYPHASE PHASE-SHIFTING APPARATUS USING THE SAME

(71) Applicant: Electronics and Telecommunications Research Institute, Daejeon (KR)

(72) Inventors: JUN HAN LIM, Daejeon (KR); Seong Mo MOON, Daejeon (KR)

(73) Assignee: Electronics and Telecommunications Research Institute, Daejeon (KR)

(21) Appl. No.: 16/692,944

(22) Filed: Nov. 22, 2019

(30) Foreign Application Priority Data
Dec. 19, 2018 (KR) 10-2018-0165614

(51) Int. Cl. H03H 11/18; H03H 7/19

(52) U.S. Cl. CPC H03H 11/18; H03H 7/19

(57) ABSTRACT

A dual-band in-phase and quadrature-phase (I/Q) signal generating apparatus and a polyphase phase-shifting apparatus using the same are provided. An I/Q signal generating circuit may include a first resonant circuit that includes a first capacitor and a first inductor and that has one end connected to an input, and a second resonant circuit that includes a second capacitor and a second inductor and that has one end connected to another end of the first resonant circuit. The other end of the first resonant circuit and the one end of the second resonant circuit may be connected to a first output.

### CROSS-REFERENCE TO RELATED APPLICATION(S)

This application claims the priority benefit of Korean Patent Application No. 10-2018-0165614 filed on Dec. 19, 2018, in the Korean Intellectual Property Office, the disclosure of which is incorporated herein by reference for all purposes.

### BACKGROUND

### 1. Field

The following example embodiments relate to a dual-band in-phase and quadrature-phase (I/Q) signal generating apparatus and a polyphase phase-shifting apparatus using the same.

### 2. Description of Related Art

A phase shifter according to a related art includes a quadrature phase generator configured to divide a differential input signal into four phases, an analog adder configured to select a specific phase from the four phases generated in the quadrature phase generator and to add selected signals, and a 50-ohm matching circuit for output matching.

Although a frequency limit is not great in the analog adder due to a wideband operating frequency of the analog adder, an operating frequency in an in-phase and quadrature-phase (I/Q) generator may be greatly limited based on a used structure or an implementation scheme.

In the phase shifter according to the related art, the I/Q generator may be implemented as a 90-degree hybrid coupler using a transmission line, or as a transmission line using a parallel-line coupler. In particular, in a coupler, a frequency band to be used is determined based on a design frequency of a ¼ wavelength line, and a length of a ¼ wavelength is about 1.6 millimeters (mm) in a silicon-based integrated circuit (IC) in a 24 gigahertz (GHz) frequency band, and accordingly it is not suitable in terms of a size of a circuit to perform an integration by implementing I/Q generator as a circuit.

To overcome the above issue, technologies of changing a transmission line to a lumped component and performing an integration are developed. However, it is impossible to obtain a wideband characteristic even though a method of using a lumped component is used.

Thus, a method of obtaining a wideband characteristic by applying a signal generation method, such as a resistor-capacitor (RC)-capacitor-resistor (CR) poly-phased filter, is provided. However, since a loss occurs when a resistor is used in a signal path, research has been conducted on a method of reducing a loss by applying an LC-CL I/Q poly-phased filter to prevent the loss.

### SUMMARY

Example embodiments provide a dual-band in-phase and quadrature-phase (I/Q) signal generation technology and a polyphase phase-shifting technology using the dual-band I/Q signal generation technology.

According to an example embodiment, there is provided an I/Q signal generating circuit including a first resonant circuit that includes a first capacitor and a first inductor and that has one end connected to an input, and a second resonant circuit that includes a second capacitor and a second inductor and that has one end connected to another end of the first resonant circuit, wherein the other end of the first resonant circuit and the one end of the second resonant circuit are connected to a first output.

In the first resonant circuit, the first capacitor and the first inductor may be connected in series, one end of the first capacitor or one end of the first inductor may be connected to the input, and another end of the first inductor or another end of the first capacitor may be connected to the first output.

In the second resonant circuit, the second capacitor and the second inductor may be connected in parallel, one end of the second capacitor and the second inductor may be connected to the first output, and another end of the second capacitor and the second inductor may be connected to a ground end.

In the first resonant circuit, the first capacitor and the first inductor may be connected in parallel, one end of the first capacitor and the first inductor may be connected to the input, and another end of the first capacitor and the first inductor may be connected to the first output.

In the second resonant circuit, the second capacitor and the second inductor may be connected in series, one end of the second capacitor or one end of the second inductor may be connected to the first output, and another end of the second capacitor or another end of the second inductor may be connected to a ground end.

The I/Q signal generating circuit may further include a resistor having one end connected to the second resonant circuit and another end connected to a ground end.

The I/Q signal generating circuit may further include a third resonant circuit that includes a third capacitor and a third inductor and that has one end connected to the input, and a fourth resonant circuit that includes a fourth capacitor and a fourth inductor and that has one end connected to another end of the third resonant circuit, wherein the other end of the third resonant circuit and the one end of the fourth resonant circuit are connected to a second output.

The first capacitor and the first inductor may be connected in series, and the third capacitor and the third inductor may be connected in parallel.

The second capacitor and the second inductor may be connected in parallel, and the fourth capacitor and the fourth inductor may be connected in series.

According to an example embodiment, there is provided a phase shifting apparatus including an I/Q signal generating circuit including a first resonant circuit that includes a first capacitor and a first inductor and that has one end connected to an input, and a second resonant circuit that includes a second capacitor and a second inductor and that has one end connected to another end of the first resonant circuit, wherein the other end of the first resonant circuit and the one end of the second resonant circuit are connected to a first output, an analog differential adder configured to selectively add signals output from the I/Q signal generating circuit, and a matching circuit configured to match outputs of the analog differential adder.

In the first resonant circuit, the first capacitor and the first inductor may be connected in series, one end of the first capacitor or one end of the first inductor may be connected to the input, and another end of the first inductor or another end of the first capacitor may be connected to the first output.

In the second resonant circuit, the second capacitor and the second inductor may be connected in parallel, one end of the second capacitor and the second inductor may be connected to the first output, and another end of the second capacitor and the second inductor may be connected to a ground end.

In the first resonant circuit, the first capacitor and the first inductor may be connected in parallel, one end of the first capacitor and the first inductor may be connected to the input, and another end of the first capacitor and the first inductor may be connected to the first output.

In the second resonant circuit, the second capacitor and the second inductor may be connected in series, one end of the second capacitor or one end of the second inductor may be connected to the first output, and another end of the second capacitor or another end of the second inductor may be connected to a ground end.

The I/Q signal generating circuit may further include a resistor having one end connected to the second resonant circuit and another end connected to a ground end.

The I/Q signal generating circuit may further include a third resonant circuit that includes a third capacitor and a third inductor and that has one end connected to the input, and a fourth resonant circuit that includes a fourth capacitor and a fourth inductor and that has one end connected to another end of the third resonant circuit. The other end of the third resonant circuit and the one end of the fourth resonant circuit may be connected to a second output.

The first capacitor and the first inductor may be connected in series, and the third capacitor and the third inductor may be connected in parallel.

The second capacitor and the second inductor may be connected in parallel, and the fourth capacitor and the fourth inductor may be connected in series.

Additional aspects of example embodiments will be set forth in part in the description which follows and, in part, will be apparent from the description, or may be learned by practice of the disclosure.

### BRIEF DESCRIPTION OF THE DRAWINGS

These and/or other aspects, features, and advantages of the present disclosure will become apparent and more readily appreciated from the following description of example embodiments, taken in conjunction with the accompanying drawings of which:

FIG. 1 is a block diagram schematically illustrating an in-phase and quadrature-phase (I/Q) signal generating circuit according to an example embodiment;

FIG. 2A is a block diagram schematically illustrating a first resonant circuit of FIG. 1;

FIG. 2B is a block diagram schematically illustrating a second resonant circuit of FIG. 1;

FIG. 3A is a circuit diagram illustrating an example of the I/Q signal generating circuit of FIG. 1;

FIG. 3B illustrates a gain based on a frequency of a circuit of FIG. 3A;

FIG. 4A is a circuit diagram illustrating another example of the I/Q signal generating circuit of FIG. 1;

FIG. 4B illustrates a gain based on a frequency of a circuit of FIG. 4A;

FIG. 5 illustrates an example of an implementation of the I/Q signal generating circuit of FIG. 1;

FIG. 6 illustrates a phase error and an amplitude error based on a frequency of a circuit of FIG. 5;

FIG. 7 illustrates a result obtained by enlarging the phase error that is based on the frequency of the circuit of FIG. 5;

FIG. 8 illustrates an image rejection ratio (IRR) performance based on a frequency in a circuit of a single-band structure and a circuit of a dual-band structure; and

FIG. 9 illustrates an example of an implementation of a phase shifting apparatus using the I/Q signal generating circuit of FIG. 1.

### DETAILED DESCRIPTION

Hereinafter, example embodiments will be described in detail with reference to the accompanying drawings. Various modifications may be made to the example embodiments, and accordingly the scope of the right of the patent application is not limited to the example embodiments. It should be understood to include all modifications, equivalents, and replacements within the scope of the right of the example embodiments.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Although terms such as “first” or “second” may be used herein to describe various components, the components are not limited by the terms. These terms are used only to distinguish one component from another component. For example, a first component may be referred to as a second component, or similarly, the second component may be referred to as the first component within the scope of the right according to the concept of the present disclosure.

Unless otherwise defined herein, all terms used herein including technical or scientific terms have the same meanings as those generally understood by one of ordinary skill in the art to which example embodiments belong. Terms defined in dictionaries generally used should be construed to have meanings matching with contextual meanings in the related art and are not to be construed as an ideal or excessively formal meaning unless otherwise defined herein.

Regarding the reference numerals assigned to the components in the drawings, it should be noted that the same components will be designated by the same reference numerals, wherever possible, even though they are shown in different drawings. Also, in describing of example embodiments, detailed description of well-known related structures or functions will be omitted when it is deemed that such description will cause ambiguous interpretation of the example embodiments.

A term “module” described herein may refer to hardware that may perform a function and an operation to be described hereinafter according to each name of a module, may refer to computer program code that may execute a specific function and operation, or may refer to an electronic recording medium, for example, a processor or a microprocessor, including computer program code that may execute a specific function and operation.

Thus, the term “module” may refer to a functional and/or structural combination of hardware for implementing the technical idea of the present disclosure and/or software for driving the hardware.

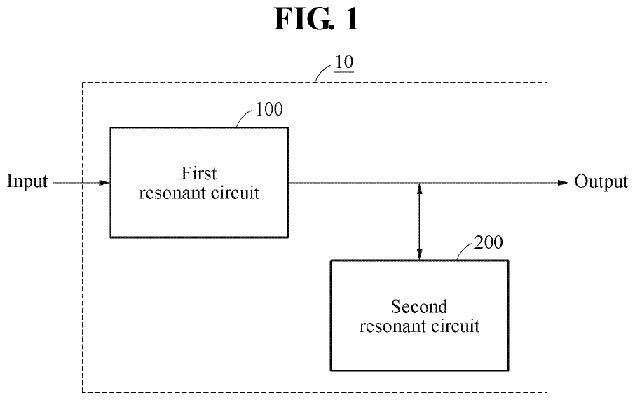

FIG. 1 is a block diagram schematically illustrating an in-phase and quadrature-phase (I/Q) signal generating circuit according to an example embodiment.

Referring to FIG. 1, an I/Q signal generating circuit 10 may process an input and generate outputs having a plurality of phases. For example, the I/Q signal generating circuit 10 may generate at least two outputs having a phase difference of 90 degrees from the input.

The I/Q signal generating circuit 10 may generate an I/Q signal based on a polyphase filter. The I/Q signal generating circuit 10 may distribute a orthogonal phase signal in an output by generating signals having phases of +45 degrees and −45 degrees with respect to the input using an LC/CL resonator.

The I/Q signal generating circuit 10 may include at least one resonant circuit. The I/Q signal generating circuit 10 may generate an I signal and a Q signal using the at least one resonant circuit. The I signal and the Q signal may refer to signals having a relative phase to difference of 90 degrees.

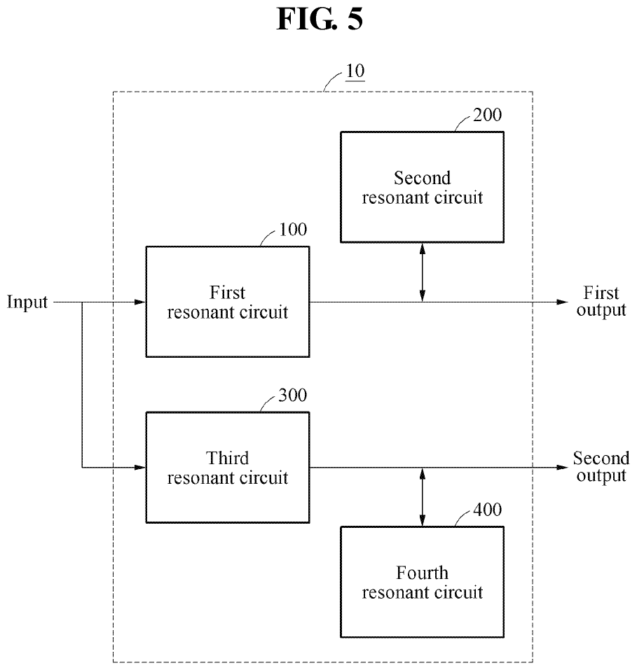

The I/Q signal generating circuit 10 may include a first resonant circuit 100 and a second resonant circuit 200. The I/Q signal generating circuit 10 may generate at least two signals having quadrature phases using the first resonant circuit 100 and the second resonant circuit 200. An operation of the I/Q signal generating circuit 10 to generate at least two signals having quadrature phases will be further described below with reference to FIG. 5.

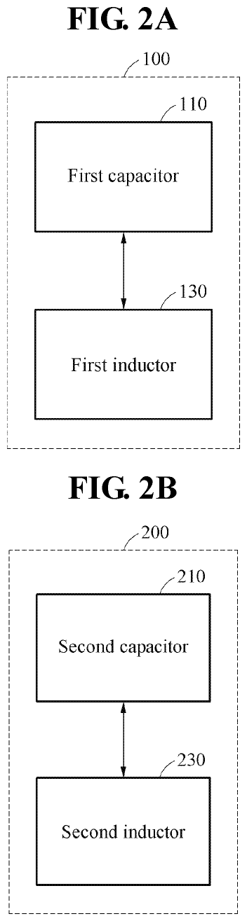

Hereinafter, an operation of the I/Q signal generating circuit 10 will be further described with reference to FIGS. 2A through 4B.

FIG. 2A is a block diagram schematically illustrating the first resonant circuit 100 of FIG. 1, and FIG. 2B is a block diagram schematically illustrating the second resonant circuit 200 of FIG. 1.

Referring to FIGS. 2A and 2B, the first resonant circuit 100 may include a first capacitor 110 and a first inductor 130. The second resonant circuit 200 may include a second capacitor 210 and a second inductor 230.

A resonant circuit may refer to a circuit in which an amplitude and/or phase of a circuit response changes based on a frequency of an external force. For example, the resonant circuit may refer to an electric circuit having a condition in which electric energy vibrates between a magnetic field of an inductor and an electric field of a capacitor because an inductive reactance and a capacitive reactance have the same magnitude.

The first resonant circuit 100 and the second resonant circuit 200 may include a series resonant circuit or a parallel resonant circuit. The first resonant circuit 100 and the second resonant circuit 200 may include an RLC resonant circuit. For example, the first resonant circuit 100 and the second resonant circuit 200 may include an LC resonant circuit.

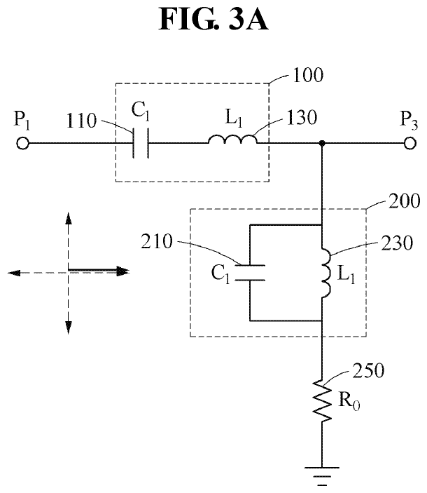

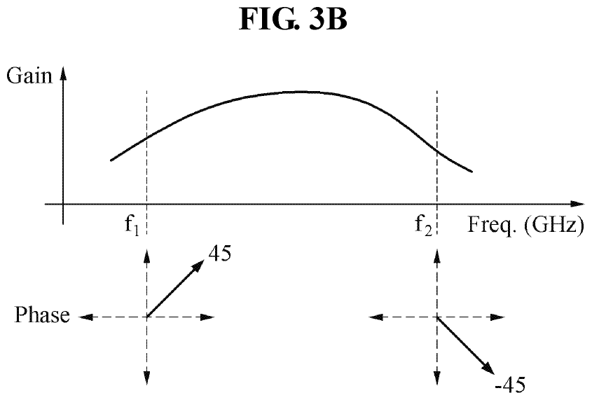

FIG. 3A is a circuit diagram illustrating an example of the I/Q signal generating circuit 10 of FIG. 1, and FIG. 3B illustrates a gain based on a frequency of a circuit of FIG. 3A.

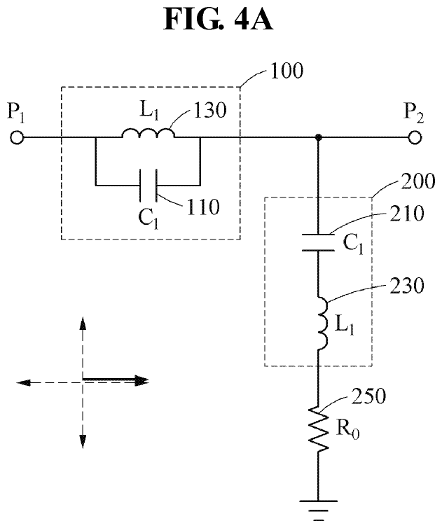

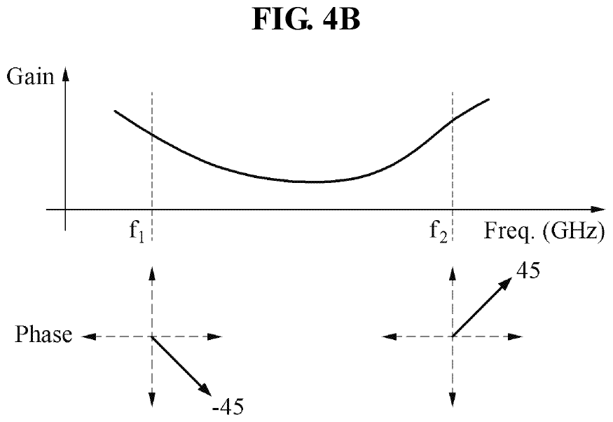

FIG. 4A is a circuit diagram illustrating another example of the I/Q signal generating circuit 10 of FIG. 1, and FIG. 4B illustrates a gain based on a frequency of a circuit of FIG. 4A.

Referring to FIGS. 3A through 4B, the I/Q signal generating circuit 10 may use the first resonant circuit 100 and the second resonant circuit 200 to generate at least two signals having quadrature phases.

The first resonant circuit 100 may include the first capacitor 110 and the first inductor 130, and may have one end connected to an input (for example, P₁). The second resonant circuit 200 may include the second capacitor 210 and the second inductor 230, and may have one end connected to another end of the first resonant circuit 100. The other end of the first resonant circuit 100 and the one end of the second resonant circuit 200 may be connected to a first output (for example, P₃).

In the example of FIG. 3A, the first capacitor 110 and the first inductor 130 of the first resonant circuit 100 may be connected in series. One end of the first capacitor 110 or one end of the first inductor 130 may be connected to the input (for example, P₁). Also, another end of the first inductor 130 or another end of the first capacitor 110 may be connected to the first output (for example, P3).

Similarly, in the example of FIG. 3A, the second capacitor 210 and the second inductor 230 of the second resonant circuit 200 may be connected in parallel. One end of the second capacitor 210 and the second inductor 230 may be connected to the first output (for example, P₃). Also, another end of the second capacitor 210 and the second inductor 230 may be connected to a ground end.

A resistor 250 may be connected between the other end of the second capacitor 210 and the second inductor 230 and the ground end. For example, one end of the resistor 250 may be connected to the second resonant circuit 200 and another end of the resistor 250 may be connected to the ground end.

Unlike the example of FIG. 3A, the I/Q signal generating circuit 10 may also be implemented to have a circuit structure as shown in FIG. 4A. For example, the first capacitor 110 and the first inductor 130 may be connected in parallel. One end of the first capacitor 110 and the first inductor 130 may be connected to the input (for example, P₁), and another end of the first capacitor 110 and the first inductor 130 may be connected to the first output (for example, P₃).

In this example, the second capacitor 210 and the second inductor 230 may be connected in series, and one end of the second capacitor 210 or one end of the second inductor 230 may be connected to the first output (for example, P₁). Also, another end of the second inductor 230 or another end of the second capacitor 210 may be connected to the ground end.

Also, the resistor 250 may be connected between the other end of the second capacitor 210 or the second inductor 230 and the ground end. For example, one end of the resistor 250 may be connected to the second resonant circuit 200 and another end of the resistor 250 may be connected to the ground end.

In an I/Q signal generating method using only a single capacitor or a single inductor instead of using a resonant circuit, a phase may be exactly 90 degrees and amplitudes may be the same in one frequency only.

The above-described structure using a single capacitor or a single inductor may typically operate in a wide band, and an operating area may be defined based on a specification of amplitude and phase errors. Also, a wideband operation may be implemented by adjusting a capacitance using a variable capacitor to operate in a wider bandwidth, however, an image rejection ratio (IRR) caused by an insertion loss may be reduced.

In an I/Q signal generating structure using a single capacitor or a single inductor, a phase error may rapidly increase as a frequency decreases in a frequency band outside a center frequency, and an operation as an I/Q signal generator may be impossible due to an extremely great amplitude error characteristic.

The I/Q signal generating circuit 10 may use a series LC resonant circuit instead of a single capacitor, and use a parallel resonant circuit instead of an inductor. Thus, sections with the same amplitudes may be generated in two frequency bands by a series/parallel resonant frequency.

Thus, it is possible to use I/Q signal generating circuit 10 even in a frequency band outside a center frequency and possible to have operating range greater than twice a structure according to a related art.

FIG. 5 illustrates an example of an implementation of the I/Q signal generating circuit 10 of FIG. 1.

Referring to FIG. 5, an I/Q signal generating circuit 10 may include a first resonant circuit 100, a second resonant circuit 200, a third resonant circuit 300 and a fourth resonant circuit 400. As described above, the first resonant circuit 100 may include a first capacitor 110 and a first inductor 130 and may have one end connected to an input (for example, P₁).

The second resonant circuit 200 may include a second capacitor 210 and a second inductor 230. One end of the second resonant circuit 200 may be connected to another end of the first resonant circuit 100, and the other end of the first resonant circuit 100 and the one end of the second resonant circuit 200 may be connected to a first output (for example, P₃).

The third resonant circuit 300 may include a third capacitor (not shown) and a third inductor (not shown), and one end of the third resonant circuit 300 may be connected to the input (for example, P₁). For example, the first resonant circuit 100 and the third resonant circuit 300 may be connected to the same input.

The fourth resonant circuit 400 may include a fourth capacitor (not shown) and a fourth inductor (not shown), and one end of the fourth resonant circuit 400 may be connected to another end of the third resonant circuit 300. The other end of the third resonant circuit 300 and the one end of the fourth resonant circuit 400 may be connected to a second output (for example, P₂).

The first resonant circuit 100 and the third resonant circuit 300 may be different from each other in a connection structure. For example, the first capacitor 110 and the first inductor 130 may be connected in series, and the third capacitor and the third inductor may be connected in parallel.

The first resonant circuit 100 and the second resonant circuit 200 may be different from each other in a connection structure. For example, the first capacitor 110 and the first inductor 130 may be connected in series, and the second capacitor 210 and the second inductor 230 may be connected in parallel.

Similarly, the second resonant circuit 200 and the fourth resonant circuit 400 may be different from each other in a connection structure. For example, the second capacitor 210 and the second inductor 230 may be connected in parallel, and the fourth capacitor and the fourth inductor may be connected in series.

In the example of FIG. 5, the first resonant circuit 100 and the fourth resonant circuit 400 may have the same circuit structure, and the second resonant circuit 200 and the third resonant circuit 300 may have the same circuit structure.

To solve a problem of a sudden increase in a phase error and an increase in an amplitude error in a band far from the center frequency, a capacitor may be changed to a series LC resonant circuit and an inductor may be replaced by a parallel resonant circuit in the I/Q signal generating circuit 10.

By using a resonant circuit instead of a single capacitor or an inductor, the I/Q signal generating circuit 10 may generate sections with the same amplitudes in two frequency bands by a series/parallel resonant frequency.

Thus, the I/Q signal generating circuit 10 may be used even in a band far from the center frequency at which a normal operation is not performed due to a great phase error and a great amplitude error, and accordingly it may be possible to implement an operating range greater than twice that of the structure according to the related art.

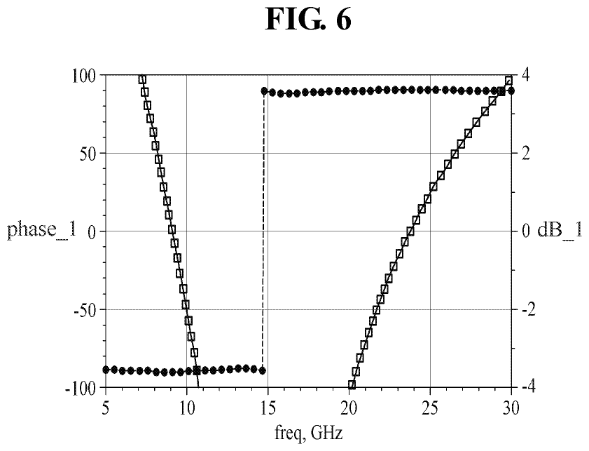

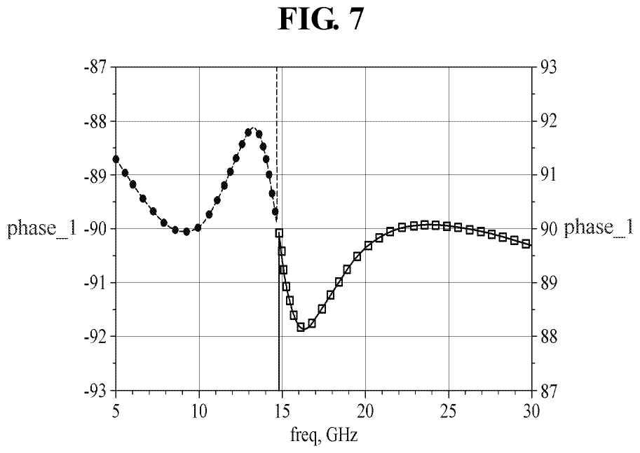

FIG. 6 illustrates a phase error and an amplitude error based on a frequency of a circuit of FIG. 5, and FIG. 7 illustrates a result obtained by enlarging the phase error that is based on the frequency of the circuit of FIG. 5.

FIGS. 6 and 7 show simulation results obtained by adjusting resonant frequency values of series/parallel resonators by an I/Q signal generating circuit 10. For example, FIG. 6 shows a simulation result obtained by adjusting a capacitance and an inductance of series/parallel resonant circuits so that the series/parallel resonant circuits may operate at central frequencies of 9 GHz and 21 GHz, respectively.

The I/Q signal generating circuit 10 may have a wideband (dual band) characteristic by operating in two frequency bands at the same time by applying a plurality of resonant circuits. Also, FIG. 7 shows a result obtained by enlarging a phase error value based on a frequency, and a phase error within 2 degrees in two band modes of 9 GHz and 21 GHz may be confirmed.

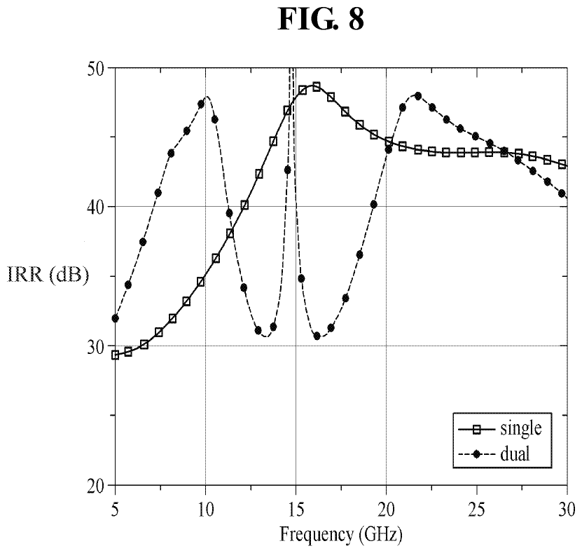

FIG. 8 illustrates an IRR performance based on a frequency in a circuit of a single-band structure and a circuit of a dual-band structure.

Referring to FIG. 8, an IRR may refer to a ratio of magnitude of phase errors and amplitude errors that occur in generation of an I signal and a Q signal, and may indicate an applicability in a dual band when the above series/parallel resonant circuit is applied.

In an I/Q signal generating circuit 10, a phase of each of an I signal and a Q signal operating in two frequency bands may be changed. However, since the phase is changed based on a band used in a signal processing end, the above change may be easily corrected by a digital end or a lookup table (LUT).

FIG. 8 shows a result obtained by comparing an IRR performance of a single-band structure according to the related art to an IRR performance of a dual-band structure, for example, the I/Q signal generating circuit 10. The I/Q signal generating circuit 10 may have a characteristic of an IRR greater than or equal to 40 dB in a dual band by using a series/parallel resonance.

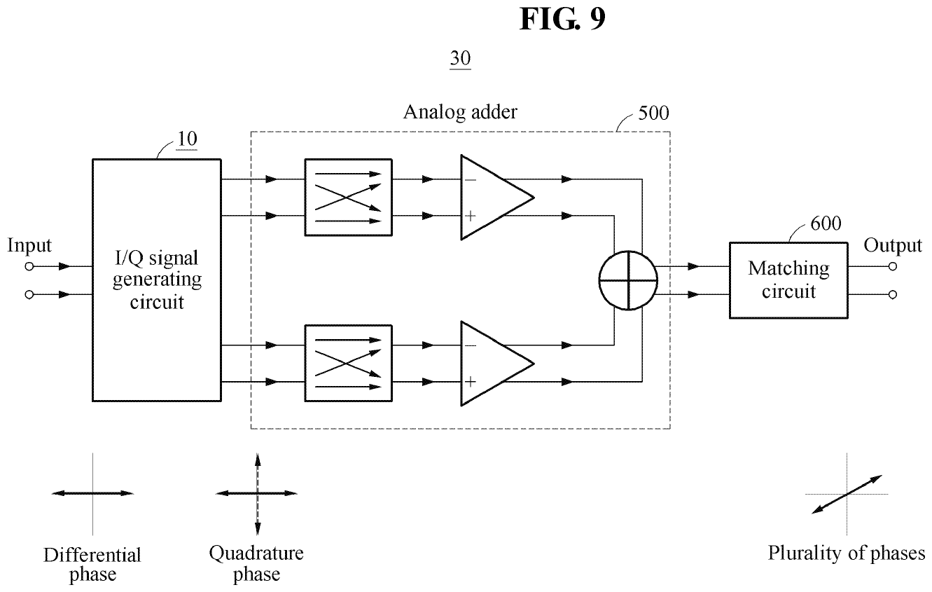

FIG. 9 illustrates an example of an implementation of a phase shifting apparatus using the I/Q signal generating circuit 10 of FIG. 1.

Referring to FIG. 9, a phase shifting apparatus 30 may include the I/Q signal generating circuit 10, an analog adder 500 and a matching circuit 600. The I/Q signal generating circuit 10 may include a first resonant circuit 100 and a second resonant circuit 200.

The first resonant circuit 100 may include a first capacitor 110 and a first inductor 130, and the second resonant circuit 200 may include a second capacitor 210 and a second inductor 230. One end of the second resonant circuit 200 may be connected to another end of the first resonant circuit 100, and the other end of the first resonant circuit 100 and the one end of the second resonant circuit 200 may be connected to a first output.

A configuration and an operation of the I/Q signal generating circuit 10 may be the same as those described above in FIGS. 1 through 8.

The I/Q signal generating circuit 10 may divide a differential input signal into four phases. For example, the I/Q signal generating circuit 10 may operate as a quadrature phase generator.

The analog adder 500 may include an analog differential adder. The analog adder 500 may selectively add signals output from the I/Q signal generating circuit 10. For example, the analog adder 500 may select a specific phase among four signals generated in the quadrature phase generator, and may add selected signals.

The matching circuit 600 may match outputs of the analog adder 500. For example, the matching circuit 600 may include a 50-ohm matching circuit for output matching.

By using the I/Q signal generating circuit 10, it is possible to implement the phase shifting apparatus 30 operating in a wide band. The phase shifting apparatus 30 may provide a wideband operating performance in one circuit. Integration into a monolithic microwave integrated circuit (MMIC) may be possible during an operation in a dual band by using the phase shifting apparatus 30, and thus a device may be miniaturized. Based on the above characteristic, the phase shifting apparatus 30 may be applied to a phase array antenna system with a subminiature wideband characteristic.

The components described in the example embodiments may be implemented by hardware components including, for example, at least one digital signal processor (DSP), a processor, a controller, an application-specific integrated circuit (ASIC), a programmable logic element, such as a field programmable gate array (FPGA), other electronic devices, or combinations thereof. At least some of the functions or the processes described in the example embodiments may be implemented by software, and the software may be recorded on a recording medium. The components, the functions, and the processes described in the example embodiments may be implemented by a combination of hardware and software.

The methods according to the above-described example embodiments may be recorded in non-transitory computer-readable media including program instructions to implement various operations of the above-described example embodiments. The media may also include, alone or in combination with the program instructions, data files, data structures, and the like. The program instructions recorded on the media may be those specially designed and constructed for the purposes of example embodiments, or they may be of the kind well-known and available to those having skill in the computer software arts. Examples of non-transitory computer-readable media include magnetic media such as hard disks, floppy disks, and magnetic tape; optical media such as CD-ROM discs, DVDs, and/or Blue-ray discs; magneto-optical media such as optical discs; and hardware devices that are specially configured to store and perform program instructions, such as read-only memory (ROM), random access memory (RAM), flash memory (e.g., USB flash drives, memory to cards, memory sticks, etc.), and the like. Examples of program instructions include both machine code, such as produced by a compiler, and files containing higher level code that may be executed by the computer using an interpreter. The above-described devices may be configured to act as one or more software modules in order to perform the operations of the above-described example embodiments, or vice versa.

The software may include a computer program, a piece of code, an instruction, or some combination thereof, to independently or collectively instruct or configure the processing device to operate as desired. Software and data may be embodied permanently or temporarily in any type of machine, component, physical or virtual equipment, computer storage medium or device, or in a propagated signal wave capable of providing instructions or data to or being interpreted by the processing device. The software also may be distributed over network coupled computer systems so that the software is stored and executed in a distributed fashion. The software and data may be stored by one or more non-transitory computer readable recording mediums.

While this disclosure includes specific examples, it will be apparent to one of ordinary skill in the art that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner and/or replaced or supplemented by other components or their equivalents.

Therefore, the scope of the disclosure is defined not by the detailed description, but by the claims and their equivalents, and all variations within the scope of the claims and their equivalents are to be construed as being included in the disclosure.

What is claimed is:

1. An in-phase and quadrature-phase (I/Q) signal generating circuit comprising:
a first resonant circuit that comprises a first capacitor and a first inductor and that has one end connected to an input; and
a second resonant circuit that comprises a second capacitor and a second inductor and that has one end connected to another end of the first resonant circuit,
wherein the other end of the first resonant circuit and the one end of the second resonant circuit are connected to a first output.

2. The I/Q signal generating circuit of claim 1, wherein in the first resonant circuit,
the first capacitor and the first inductor are connected in series,
one end of the first capacitor or one end of the first inductor is connected to the input, and
another end of the first inductor or another end of the first capacitor is connected to the first output.

3. The I/Q signal generating circuit of claim 2, wherein in the second resonant circuit,
the second capacitor and the second inductor are connected in parallel,
one end of the second capacitor and the second inductor are connected to the first output, and
another end of the second capacitor and the second inductor are connected to a ground end.

4. The I/Q signal generating circuit of claim 1, wherein in the first resonant circuit,
the first capacitor and the first inductor are connected in parallel,
one end of the first capacitor and the first inductor are connected to the input, and
another end of the first capacitor and the first inductor are connected to the first output.

5. The I/Q signal generating circuit of claim 4, wherein in the second resonant circuit,
to the second capacitor and the second inductor are connected in series,
one end of the second capacitor or one end of the second inductor is connected to the first output, and
another end of the second capacitor or another end of the second inductor is connected to a ground end.

6. The I/Q signal generating circuit of claim 1, further comprising:
a resistor having one end connected to the second resonant circuit and another end connected to a ground end.

7. The I/Q signal generating circuit of claim 1, further comprising:
a third resonant circuit that includes a third capacitor and a third inductor and that has one end connected to the input; and
a fourth resonant circuit that includes a fourth capacitor and a fourth inductor and that has one end connected to another end of the third resonant circuit,
wherein the other end of the third resonant circuit and the one end of the fourth resonant circuit are connected to a second output.

8. The I/Q signal generating circuit of claim 7, wherein
the first capacitor and the first inductor are connected in series, and
the third capacitor and the third inductor are connected in parallel.

9. The I/Q signal generating circuit of claim 8, wherein
the second capacitor and the second inductor are connected in parallel, and
the fourth capacitor and the fourth inductor are connected in series.

10. A phase shifting apparatus comprising:
an in-phase and quadrature-phase (I/Q) signal generating circuit comprising a first resonant circuit that comprises a first capacitor and a first inductor and that has one end connected to an input, and a second resonant circuit that comprises a second capacitor and a second inductor and that has one end connected to another end of the first resonant circuit, wherein the other end of the first resonant circuit and the one end of the second resonant circuit are connected to a first output;
an analog differential adder configured to selectively add signals output from the I/Q signal generating circuit; and
a matching circuit configured to match outputs of the analog differential adder.

11. The phase shifting apparatus of claim 10, wherein in the first resonant circuit,
the first capacitor and the first inductor are connected in series,
one end of the first capacitor or one end of the first inductor is connected to the input, and
another end of the first inductor or another end of the first capacitor is connected to the first output.

12. The phase shifting apparatus of claim 11, wherein in the second resonant circuit,
the second capacitor and the second inductor are connected in parallel,
one end of the second capacitor and the second inductor are connected to the first output, and
another end of the second capacitor and the second inductor are connected to a ground end.

13. The phase shifting apparatus of claim 10, wherein in the first resonant circuit,
the first capacitor and the first inductor are connected in parallel,
one end of the first capacitor and the first inductor are connected to the input, and
another end of the first capacitor and the first inductor are connected to the first output.

14. The phase shifting apparatus of claim 13, wherein in the second resonant circuit,
the second capacitor and the second inductor are connected in series,
one end of the second capacitor or one end of the second inductor is connected to the first output, and
another end of the second capacitor or another end of the second inductor is connected to a ground end.

15. The phase shifting apparatus of claim 10, wherein the I/Q signal generating circuit further comprises a resistor having one end connected to the second resonant circuit and another end connected to a ground end.

16. The phase shifting apparatus of claim 10, wherein the I/Q signal generating circuit further comprises:
a third resonant circuit that includes a third capacitor and a third inductor and that has one end connected to the input; and
a fourth resonant circuit that includes a fourth capacitor and a fourth inductor and that has one end connected to another end of the third resonant circuit,
wherein the other end of the third resonant circuit and the one end of the fourth resonant circuit are connected to a second output.

17. The phase shifting apparatus of claim 16, wherein
the first capacitor and the first inductor are connected in series, and
the third capacitor and the third inductor are connected in parallel.

18. The phase shifting apparatus of claim 17, wherein
the second capacitor and the second inductor are connected in parallel, and
the fourth capacitor and the fourth inductor are connected in series.
